(19) United States
(12) Patent Application Publication
(10) Pub. No.: US 2025/0199768 A1
(43) Pub. Date: Jun. 19, 2025

(54) HARDWARE EFFICIENT OUT-OF-ORDER SYNDROME CALCULATION

(71) Applicant: SAMSUNG ELECTRONICS CO., LTD., SUWON-SI (KR)

(72) Inventors: AMIT BERMAN, Tel-Aviv (IE); DIKLA SHAPIRO, Tel-Aviv (IE)

(21) Appl. No.: 18/389,602

(22) Filed: Dec. 19, 2023

(51) Int. Cl. G06F 7/544; G06F 11/10

(52) U.S. Cl. CPC G06F 7/5443; G06F 11/1044

(57) ABSTRACT

A hardware circuit for calculating syndromes in Reed-Solomon (RS) error correction codes comprises a plurality of p multiplexors, where p is a positive integer, where each multiplexor receives α\hat{ }i powers that are selected by j, wherein α is a primitive point of a RS generator polynomial and j is an index of an RS symbol, where i and j are positive integers, where 1≤i≤p, and outputs α\hat{ }(i×j); and a plurality of p first multipliers, where each first multiplier is associated with a multiplexor and receives α\hat{ }(i×j) from the associated multiplexor, multiplies the α\hat{ }(i×j) by a jth RS-word symbol Rⱼ and outputs Rⱼ×α\hat{ }(i×j). The hardware circuit calculates and outputs p products of the form Rⱼ×α\hat{ }(i×j), wherein 1≤i≤p.

### TECHNICAL FIELD

Embodiments of the present disclosure are directed to syndrome calculations in generalized concatenated error correction codes.

### DISCUSSION OF THE RELATED ART

Reed-Solomon (RS) codes are a group of error-correcting codes used for correcting errors in data transmitted over unreliable or noisy communication channels. The transmitted message (c₀, . . . , cᵢ, . . . , cₙ₋₁) can be viewed as the coefficients of a polynomial:

$$s ( x ) = {\sum }_{i = 0}^{n - 1} {c}_{i} {x}^{i} .$$

The transmitted polynomial is corrupted in transit by an error polynomial e(x) to produce the received polynomial r(x)″

$$r ( x ) = s ( x ) + e ( x ) , where e ( x ) = {\sum }_{i = 1}^{n - 1} {e}_{i} {x}^{i} .$$

Coefficient eᵢ will be zero if there is no error at that power of x and nonzero if there is an error. The decoder starts by evaluating the polynomial as received at points α¹ . . . α^{n-k}, where the α's are primitive elements of the RS generator polynomial. These results are referred to as the syndromes Sⱼ.

A RS syndrome calculation can be described as follows:

$${S}_{m} = \sum {α}^{j m} \times {F}_{j} ,$$

Where m refers to the mth syndrome, where m=1, . . . , D, and F, is the j-th symbol of the RS codeword, which is a delta-frozen symbol of the jth frame in a generalized concatenated (GCC) code, where a frame (or row) is a codeword of the inner code in a GCC, which, in embodiments of the disclosure, is a polar or BCH code. In an SPolar code, the inner code is a Polar code, and the outer code is an RS code. A delta-frozen symbol refers to the additional parity of a polar frame.

### SUMMARY

Embodiments of the disclosure can calculate D Syndromes for each Reed-Solomon Decoding.

Embodiments of the disclosure can receive the symbols in any order, and calculate the addition for all syndromes.

Embodiments of the disclosure can maintain a Reed-Solomon syndrome (RSS) for RS decoding between activations.

According to an embodiment of the disclosure, there is provided a hardware circuit for calculating syndromes in Reed-Solomon (RS) error correction codes. The hardware circuit comprises a plurality of p multiplexors, wherein p is a positive integer, wherein each multiplexor receives α\hat{ }i powers that are selected by j, wherein α is a primitive point of a RS generator polynomial and j is an index of an RS symbol, wherein i and j are positive integers, wherein 1≤i≤p, and outputs α\hat{ }(i×j); and a plurality of p first multipliers, wherein each first multiplier is associated with a multiplexor and receives α\hat{ }(i×j) from the associated multiplexor, multiplies the α\hat{ }(i×j) by a jth RS-word symbol Rⱼ and outputs Rⱼ×α\hat{ }(i×j). The hardware circuit calculates and outputs p products of the form Rⱼ×α\hat{ }(i×j), wherein 1≤i≤p.

According to a further embodiment of the disclosure, the hardware circuit comprises a plurality of p second multipliers, where each second multiplier is associated with a multiplexor, and receives α\hat{ }(i×j) from the associated multiplexor and Rⱼ×α\hat{ }(p×j) from a pth first multiplier of the plurality of first multipliers, and multiplies the Rⱼ×α\hat{ }(p×j) by the α\hat{ }(i×j). The hardware circuit further calculates and outputs p products of the form Rⱼ×α\hat{ }((i+p)×j), wherein 1≤i≤p.

According to a further embodiment of the disclosure, for n syndromes, where n=2×p×m, where n and m are positive integers, the circuit repeats calculating and outputting a next 2×p products m times, wherein the jth RS-word symbol Rⱼ for a kth iteration is replaced by Rⱼ×α\hat{ }(2pj) from a (k−1)th iteration, wherein 1≤k≤m.

According to a further embodiment of the disclosure, the hardware circuit comprises a plurality of p second multipliers, where each second multiplier receives the product Rⱼ×α\hat{ }(i×j), wherein 1≤i≤p, multiplies the product Rx α\hat{ }(i×j) by α\hat{ }(pj) and outputs a result Rⱼ×α\hat{ }((i+p)×j).

According to a further embodiment of the disclosure, for n syndromes, where n=2×p×m, where n and m are positive integers, the circuit repeats calculating and outputting a next p products m times, wherein the jth RS-word symbol Rⱼ for a kth iteration is replaced by Rⱼ×α\hat{ }(2pj) from a (k−1)th iteration, wherein 1≤k≤m, and multiplies each of the p products by α\hat{ }(pj) and outputs a result thereof.

According to a further embodiment of the disclosure, the hardware circuit comprises a first GF-square hardware unit connected to an output of each multiplexor, where the GF-square hardware unit squares the α\hat{ }(i×j) received from the connected multiplexor; a first register, a second register, and a third register, where the first register stores a result α\hat{ }2(i×j) received from the first GF-square hardware unit, the second register stores a result Rⱼ×α\hat{ }(i×j) received from a first multiplier associated with the connected multiplexor, and the third register stores the jth RS-word symbol Rⱼ; a first iterative multiplier that calculates a first product of the result stored in the first register and the result Rⱼ×α\hat{ }(i×j) stored in the second register, and outputs the first product; and a second iterative multiplier that calculates a second product of the result stored in the first register and the jth RS-word symbol Rⱼ and outputs the second product. The result α\hat{ }2(i×j) stored in the first register is kept stable for all subsequent calculations of the syndrome.

According to a further embodiment of the disclosure, the hardware circuit comprises a first pipeline multiplexor disposed between the first multiplier of each multiplexer and the second register; and a second pipeline multiplexor disposed between an input line for the jth RS-word symbol Rⱼ and the third register. The first pipeline multiplexor receives the first product from the first iterative multiplier, the second pipeline multiplexor receives the second product from the second iterative multiplier, and each of the first and second pipeline multiplexor respectively selects the first product and the second product for a new calculation of Rⱼ×α\hat{ }(i×j) and Rⱼ×α\hat{ }((i+p)×j) while a previous calculation of Rⱼ×α\hat{ }(i×j) and Rⱼ×α\hat{ }((i+p)×j) is still in progress.

According to a further embodiment of the disclosure, the hardware circuit comprises a second GF-square hardware unit connected to an output of each first GF-square hardware unit, where the GF-square hardware unit squares the α\hat{ }(2j) received from the connected first GF-square hardware unit; a third iterative multiplier that calculates a third product of a result α\hat{ }(4j) received from the second GF-square hardware unit and the result Rⱼ×α\hat{ }(i×j) stored in the second register, and outputs the third product, and a fourth iterative multiplier that calculates a fourth product of the result α\hat{ }(4j) received from the second GF-square hardware unit and the jth RS-word symbol Rⱼ stored in the third register, and outputs the second product.

According to a further embodiment of the disclosure, the hardware circuit comprises a fourth register disposed between the second GF-square hardware unit and the third iterative multiplier, and that stores the result α\hat{ }(4j) received from the second GF-square hardware unit.

### BRIEF DESCRIPTION OF THE DRAWINGS

FIGS. 1A and 1B illustrate hardware that calculates the i-th syndrome using Horner's Rule, for all symbols, according to embodiments of the disclosure.

FIG. 2 illustrates hardware that calculates and accumulates the contribution of each symbol, rⱼ, to the syndrome, according to embodiments of the disclosure.

FIGS. 3A, 3B, 3C, 3D, and 3E illustrate decoding of generalized concatenated error correction code words, according to embodiments of the disclosure.

FIG. 4 illustrates an exemplary hardware for a specific syndrome i, according to embodiments of the disclosure.

FIG. 5 illustrates hardware for an iterative calculation, according to embodiments of the disclosure.

FIGS. 6A and 6B illustrate hardware that, from the 2nd iteration on, samples α^{ij} in registers or keeps α^{ij} stable, and implements the 2nd 2 sets (or more) with only 2 multipliers, according to embodiments of the disclosure.

### DETAILED DESCRIPTION

Hereinafter, embodiments of the present disclosure will be described with reference to accompanying drawings.

Two options for calculating syndromes are as follows.

### Option 1: Horner Rule

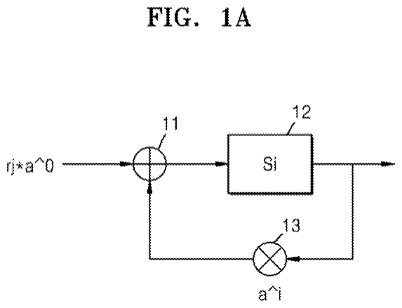

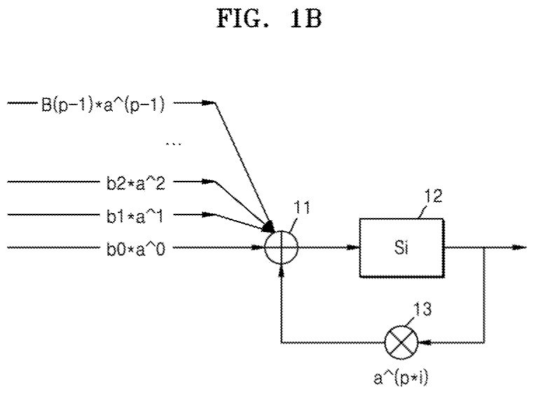

The Horner rule is very efficient when symbols are received in order. For each syndrome Sᵢ, (i=0, . . . , D−1), the syndrome value is the evaluation of the input polynomial in αⁱ. The input symbols are referred to as polynomial coefficients, received from the highest degree. The syndrome calculation for all sequential symbols (RS word) can be implemented by Horner rule, optionally with parallelism. When the codeword symbols are received in order, the accumulative result is multiplied by a, and the new symbol is added each time. When all symbols have been received, the syndrome is ready. FIGS. 1A and 1B illustrate hardware that calculates the i-th syndrome, for all symbols. FIG. 1A shows hardware that calculates the i-th syndrome using the Horner rule without parallelism, and includes an adder 11, an accumulator 12 and a multiplier 13. The adder 11 sums the input rⱼα⁰, where rⱼ is the coefficient of the jth term and α is a primitive element, with the product of the ith primitive element a with the result accumulated in the accumulator 11 received from the multiplier 13, and the accumulator accumulates successive results of the sum received from the adder 11. However, the Horner rule implementation is not efficient for SPolar architecture as-is, as the syndrome is updated on-the-fly and not in order. FIG. 1B shows hardware that calculates the i-th syndrome using the Horner rule with parallelism of p inputs. In particular, the hardware of FIG. 1B can process p inputs in parallel, where b(p−i) is the coefficient of the (p−i+1)th term, but the p inputs are received in order to work correctly.

Option 2: General HW for Syndrome Sᵢ from Symbol j:

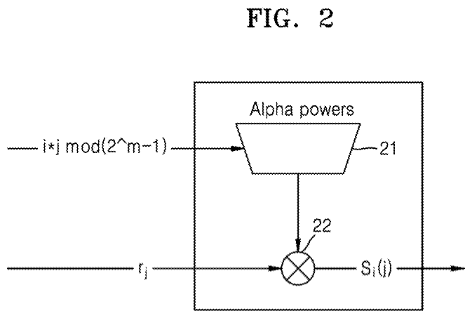

Another option for syndrome calculation is to calculate the contribution of each symbol, rⱼ, to the syndrome and accumulate it, as shown in FIG. 2. The figure illustrates the naive hardware solution for a syndrome calculation, when the word symbols are received out of order. The hardware calculates the i-th syndrome. The figures shows multiplexor 21, which outputs a power of the primitive element a selected by (i×j)mod((2\hat{ }m)−1) of the mth syndrome, and multiplier 22 that receives the j-th symbol, with its index (j), and the selected α, and outputs the contribution of this symbol to the i-th syndrome. To get the total result of the i-th syndrome, the contribution of all symbols is accumulated (XORed).

A direct implementation may be configured with more hardware. This method uses a general Galois field (GF) multiplier per syndrome, while the Horner implementation uses a constant-multiplier, and option 2 is configured with a preliminary calculation of i×j mod (2^{m}−1) per syndrome.

However, the second option has few advantages over Horner-rule hardware: When symbols arrive out of order, option two is easier and faster to use, and hardware (HW) parallelism for different syndromes Sᵢ is possible. However, an embodiment may calculate about 70 RS syndromes for a word in the first column, and use fewer than 70 hardware “boxes”, and just update the “i×j” result. Further, there is a latency, since the syndrome update calculation (per frame) takes 1 cycle.

### Generalized Concatenated Error Codes

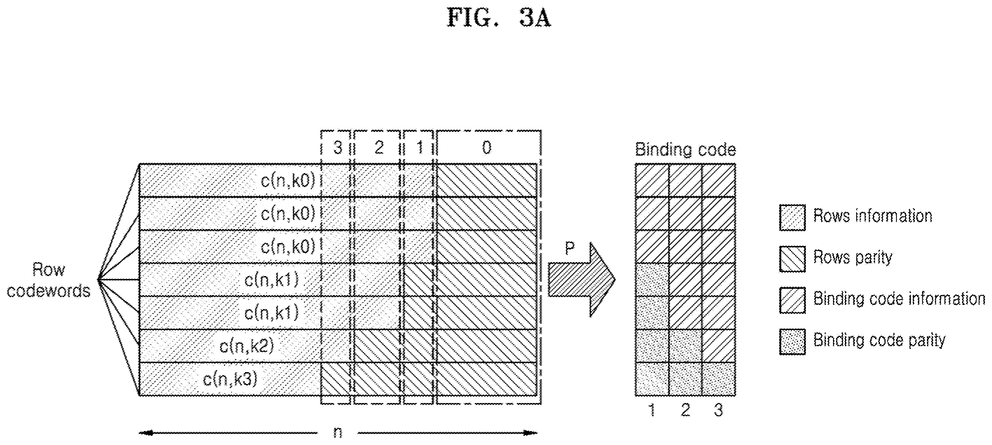

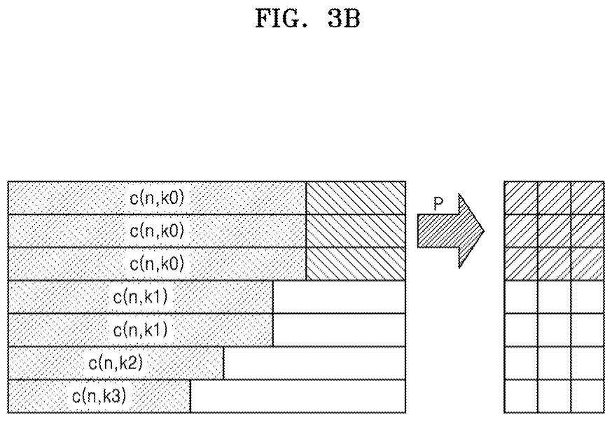

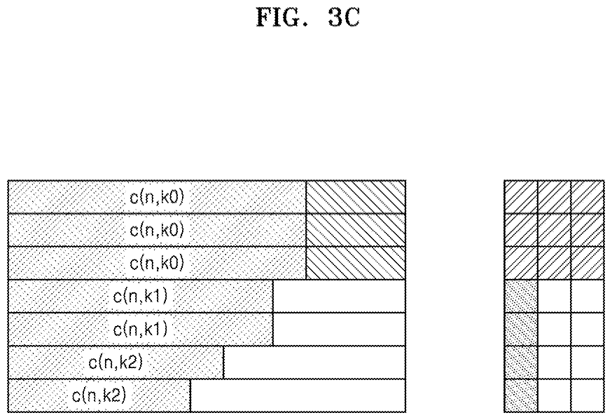

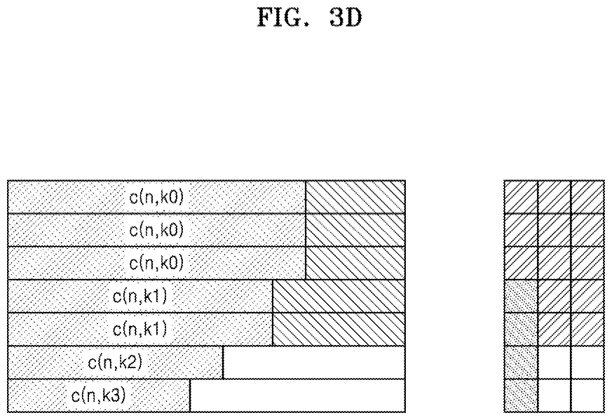

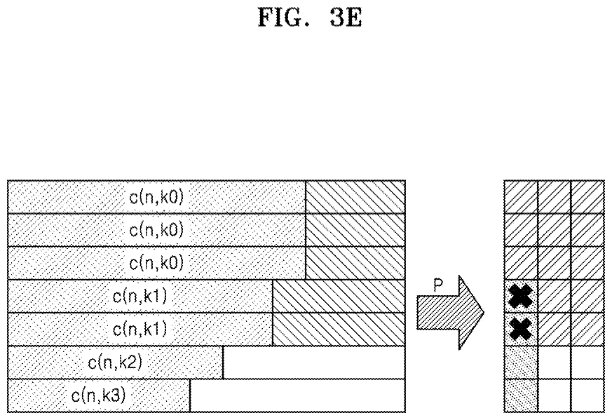

Generalized concatenated codes are two dimensional structures where rows of codewords are bonded together by a different code. In other words, the codewords meet together with a joint constraint. FIGS. 3A, 3B, 3C, 3D, and 3E illustrate decoding of generalized concatenated error correction code words, according to embodiments of the disclosure. An example is the SPolar code, in which the inner code is a Polar code, and the outer (binding) code is an RS code. The left side of FIG. 3A shows a block of generalized concatenated code words c(n, kᵢ), where n is the length of the code, and kᵢ is the dimension of the code.

All rows are of the same length n but different dimensions k. In the encoding process, the code words are grouped to S stages by their dimensions, so that each stage s, where s=1, . . . , S−1, contains all words c(n, kₛ), where s refers to a specific stage, and S is the number of stages. In FIGS. 3A-3E, S=4. Note that RS columns are associated with the stage, but they are not part of the codeword itself. They only define the constraints on the parity. Stages 0, 1, 2 and 3, are indicated by numbered vertically oriented boxes in FIG. 3A, and the associated binding codes on the right side are similarly labeled. The encoder encodes each row with parity that will satisfy RS codeword. Each word is multiplied by some matrix P that produces a row of symbols in an auxiliary matrix, shown on the right side of FIG. 3A. The auxiliary matrix columns are codewords in the binding code. The number of columns is at least S−1, and each column is associated to some stage and has the same number of information symbols as the number of rows in that stage.

After all rows of stage s are encoded, the encoder computes their P transform and obtains all the information symbols of the relevant columns in the auxiliary matrix. FIG. 3B shows the rows for stage s=0 and transformed into the auxiliary matrix on the right.

Referring to FIG. 3C, the encoders of stage s columns are activated and all the column symbols are computed. Referring to FIG. 3D, the next stage starts, and its rows are encoded. Referring to FIG. 3E, the P transform is activated on the recently encoded rows, but some of the right-hand side symbols were already determined. The symbols in the auxiliary matrix that are marked with an X are parities of the binding code and are also the results of the row's P transform. This conflict is resolved by adding affine constraints Pc=d to the rows codes, where d is determined by the auxiliary matrix.

Traditional methods of decoding GCCs decode all rows, and then calculate RS syndromes for the first column. However, it is time consuming to calculate the delta-syndromes, and storing them somewhere may also increase the overhead. It would be more efficient to calculate syndromes on-the-fly, and to have a greedy algorithm that, when enough rows are decoded, perform RS decoding and proceed to a higher stage of the decoding, without waiting for all rows to be decoded. This involves decoding the rows out of order. Note that Horner's method uses the locality property of polynomials, and multiplies the coefficient by the same power of α at each step. This calculation will not work for out-of-order α's.

### Iterative Parallel Hardware to Handle Single RSS Column

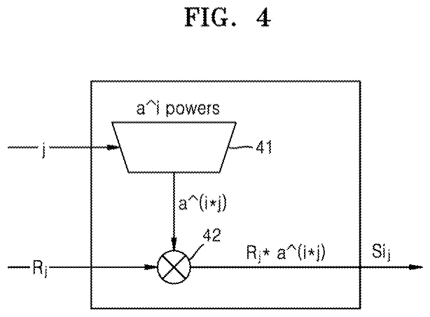

Embodiments of the disclosure use an iterative parallel hardware to handle single RSS column. In a first step, the general multiplier is eliminated by defining Si specific hardware. For a known syndrome, Sᵢ, the contribution of the j-th frame will be Rⱼ×α^{ij}, where Rⱼ is the j-th RS-word symbol. An exemplary hardware for specific syndrome i is illustrated in FIG. 4, which shows multiplexor 41 and multiplier 42. Instead of calculating i×j and then getting α^{ij} from a multiplexer of a powers, the multiplexer 41 of αⁱ powers is used, selected by j only, and the multiplier 42 outputs the product of the selected power of α and the j-th RS-word symbol Rⱼ. Although this solution spares the multiplier of i×j, it may be configured with a special multiplexer of a powers for each syndrome i, i=1, 2, . . . , D.

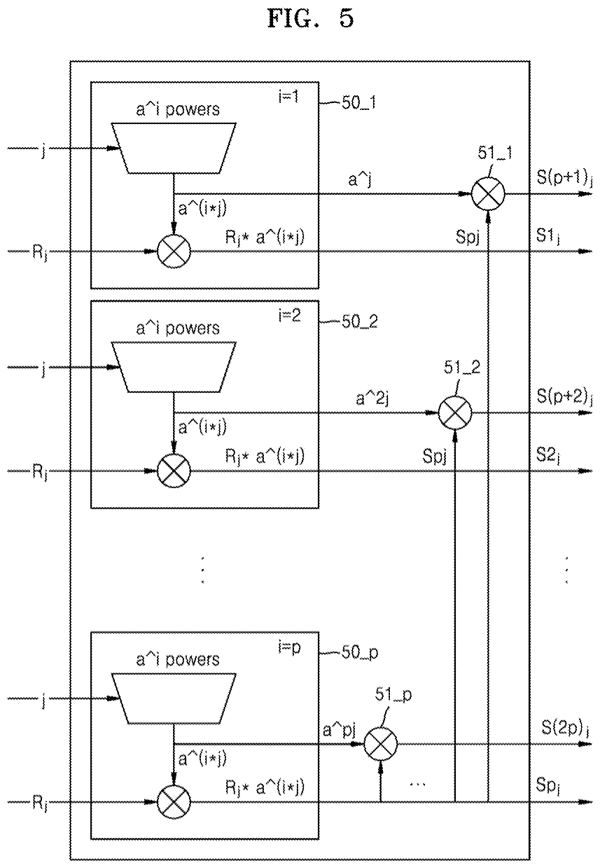

A next step involves an iterative calculation, illustrated in FIG. 5. An iterative calculation according to embodiments of the disclosure re-uses the basic HW shown in FIG. 4 in a few iterations to complete all syndrome updates by the symbol Rⱼ. FIG. 5 shows basic hardware units 50_1, 50_2, . . . , 50_p, where p is a positive integer. For convenience of illustration, the individual components of each basic hardware unit are not labeled. Each basic hardware unit shown in FIG. 5 is associated with an additional GF multiplier 51_1, 51_2, . . . , 51_p, respectively. For example: to update 40 syndromes with the j-th symbol, instead of having 40 parallel hardware units, one can select parallelism, for example, p=5, and repeat the calculation 40/(5×2)=4 times. For example, 5 instances of HW will output calculation for the first 5 syndromes (addition) S₁, S₂, . . . , S₅. With the additional GF multiplier, another set of additions to syndromes S₆, . . . , S₁₀ can be obtained. In the next cycle, with feedback of the last calculation (S(2p)ⱼ) to the Rⱼ input, instead of the original syndrome, another 5+5 syndromes S₁₁, . . . , S₁₅, S₁₆, . . . , S₂₀ are obtained.

Notice that for the ith instance of the hardware that calculates the ith RS syndrome (HWᵢ), there is an alpha power of i×j, and taking the last syndrome Rⱼ×α^{pj} for some parallelism p, and multiplying it by alpha powers, a 2nd set of syndromes p+1 . . . 2p is obtained. In the subsequent cycle(s), the last syndrome (S_{2P}) is multiplexed to R inputs, and the next 2P results are received.

In an alternative embodiment, note that the same solution can be obtained if α^{pj} is taken out of the last module, and multiplied by the calculated syndromes S₁ to Sₚ. For an SPolar implementation, both embodiments are substantially the same, although they may very slightly differ in area/power/timing, depending on other design parameters.

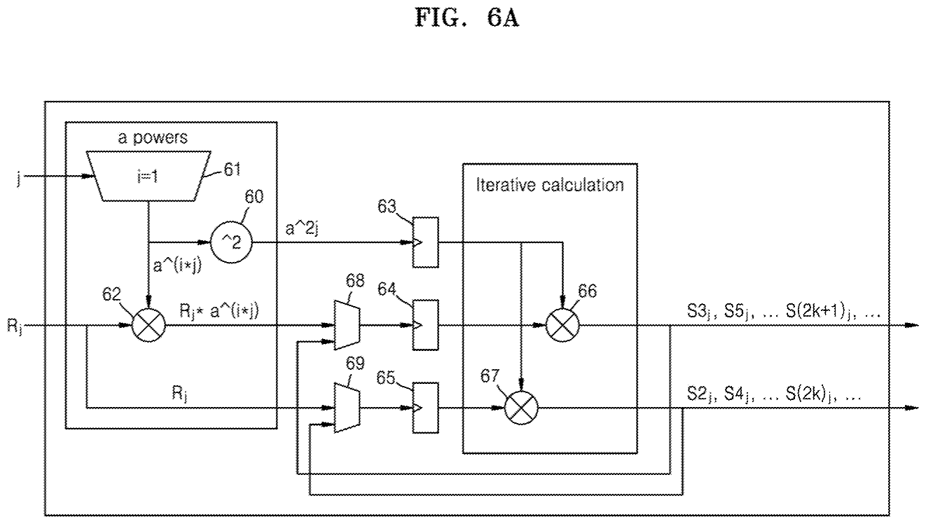

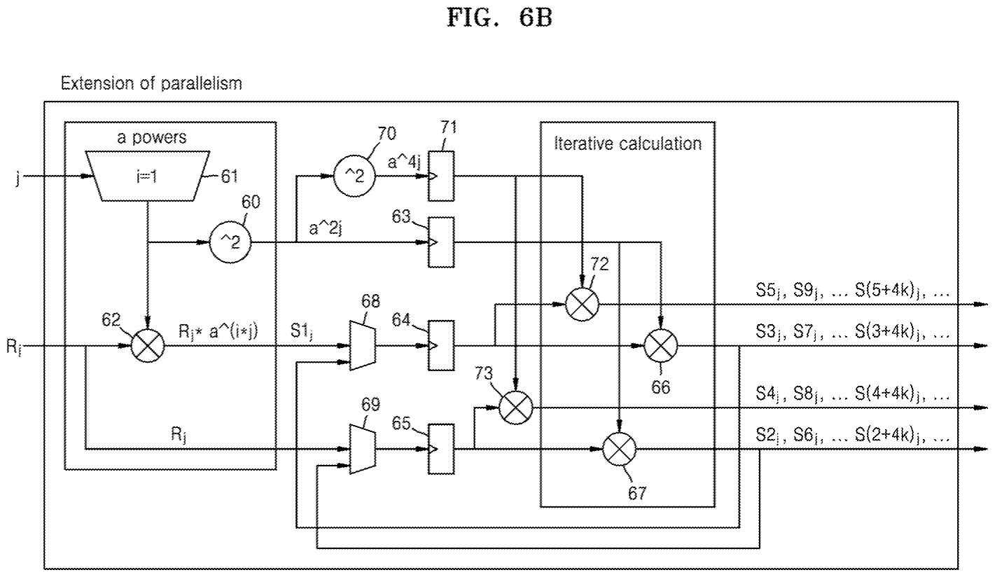

Embodiments provide further area optimizations. FIG. 6A shows a basic hardware unit with multiplexor 61, multiplier 62, and GF-square hardware unit 60, registers 63, 64, and 65, iterative multipliers 66 and 67, and pipeline multiplexors 68 and 69. Referring to FIG. 6, for example, from the 2nd iteration on, α^{ij} can be sampled or kept stable in the registers 63, 64 and 65, and 2nd 2 sets (or more) can be implemented with only the 2 iterative multipliers 66 and 67. Since α^{ij} powers are actually common to all RS symbol (RSS) columns, if they are calculated once, the 2nd iteration hardware can be used for all calculations. This optimization obtains α^{2j} from α^{j}, using GF-square hardware unit 60 only, and thus achieve double throughput, without using a multiplier. GF-square hardware unit has a relatively small size, as it uses few XOR gates. In addition, it supports pipeline architecture, using the pipeline multiplexers 68 and 69, as it enables starting a new calculation when the previous one is still in the iterative calculation stage. Even powers of alpha, 2i, can be derived from i powers with GF-square hardware unit 60, which has a relatively small size, estimated to be few XOR gates. For the first RSS column in an SPolar code, the results are provided as fast as possible, but the next columns have a slow calculation in the background.

Using an alternative embodiment described above, and sampling the results to registers before updating the RSS column, only α^{pj} should be kept, and 2-3 syndromes per cycle can be calculated in the background.

Another iterative unit of multiplying by α^{4j} can be added in parallel to α^{2j}, shown in FIG. 6B, where the same reference numbers refer to the same components in FIG. 6A, with reduced or minimal timing cost of square calculation and area cost of 2 multipliers and square. FIG. 6B includes, in addition to the components of FIG. 6A, a GF-square hardware unit 70, register 71, and iterative multipliers 72 and 73, Notice that the alpha powers logic in the left HW module in FIG. 5 can also be shared between several RSS columns, based on receiving α^{j} and α^{2j}. FIG. B shows that more calculations can be performed per second with reduced or minimal additional hardware, primarily an additional GF square hardware (minimal) and two more GF multipliers in the iterative hardware.

### Throughput (TP) and Area Tradeoff

The number of GF multipliers configured in the first and in the second phase, where the first phase includes the alpha powers and second phase is the iterative HW, depends on the expected TP. Planning the logic of RSS update should take into account the throughput configuration: the rate that updates are received, and the number of syndromes configured to calculate.

While the present disclosure has been described in detail with reference to exemplary embodiments, those skilled in the art will appreciate that various modifications and substitutions can be made thereto without departing from the spirit and scope of the disclosure as set forth in the appended claims.

What is claimed is:

1. A hardware circuit for calculating syndromes in Reed-Solomon (RS) error correction codes, comprising:
a plurality of p multiplexors, wherein p is a positive integer, wherein each multiplexor is configured to:
receive α\hat{ }i powers that are selected by j, wherein α is a primitive point of a RS generator polynomial and j is an index of an RS symbol, wherein i and j are positive integers, wherein 1≤i≤p, and outputs α\hat{ }(i×j); and
a plurality of p first multipliers, wherein each first multiplier is associated with a multiplexor and is configured to:
receive α\hat{ }(i×j) from the associated multiplexor,
multiply the α\hat{ }(i×j) by a jth RS-word symbol Rⱼ, and
output Rⱼ×α\hat{ }(i×j),
wherein the hardware circuit calculates and outputs p products of the form Rⱼ×α\hat{ }(i×j), wherein 1≤i≤p.

2. The hardware circuit of claim 1, further comprising:
a plurality of p second multipliers, wherein each second multiplier is associated with a multiplexor, and is configured to:
receive α\hat{ }(i×j) from the associated multiplexor and Rⱼ×α\hat{ }(p×j) from a pth first multiplier of the plurality of first multipliers, and
multiply the Rⱼ×α\hat{ }(p×j) by the α\hat{ }(i×j),
wherein the hardware circuit is further configured to calculate and output p products of the form Rⱼ×α\hat{ }((i+p)×j), wherein 1≤i≤p.

3. The hardware circuit of claim 2, wherein for n syndromes, wherein n=2×p×m, wherein n and m are positive integers, the circuit is configured to repeat calculating and outputting a next 2×p products m times, wherein the jth RS-word symbol Rⱼ for a kth iteration is replaced by Rⱼ×α\hat{ }(2pj) from a (k−1)th iteration, wherein 1≤k≤m.

4. The hardware circuit of claim 1, further comprising:
a plurality of p second multipliers, wherein each second multiplier is configured to:
receive the product Rⱼ×α\hat{ }(i×j), wherein 1≤i≤p,
multiply the product Rⱼ×α\hat{ }(i×j) by α\hat{ }(pj), and
output a result Rⱼ×α\hat{ }((i+p)×j).

5. The hardware circuit of claim 4, wherein for n syndromes, wherein n=2×p×m, wherein n and m are positive integers, the circuit is configured to: repeat calculating and outputting a next p products m times, wherein the jth RS-word symbol Rⱼ for a kth iteration is replaced by Rⱼ×α\hat{ }(2pj) from a (k−1)th iteration, wherein 1≤k≤m, and multiplies each of the p products by α\hat{ }(pj).

6. The hardware circuit of claim 1, further comprising:
a first GF-square hardware unit connected to an output of each multiplexor, wherein the GF-square hardware unit squares the α\hat{ }(i×j) received from the connected multiplexor;
a first register, a second register, and a third register, wherein the first register is configured to store a result α\hat{ }2(i×j) received from the first GF-square hardware unit, the second register is configured to store a result Rⱼ×α\hat{ }(i×j) received from a first multiplier associated with the connected multiplexor, and the third register is configured to store the jth RS-word symbol Rⱼ;
a first iterative multiplier configured to calculate a first product of the result stored in the first register and the result Rⱼ×α\hat{ }(i×j) stored in the second register, and output the first product; and
a second iterative multiplier configured to calculate a second product of the result stored in the first register and the jth RS-word symbol Rⱼ, and output the second product,
wherein the result α\hat{ }2(i×j) stored in the first register is kept stable for all subsequent calculations of the syndrome.

7. The hardware circuit of claim 6, further comprising:
a first pipeline multiplexor disposed between the first multiplier of each multiplexer and the second register; and
a second pipeline multiplexor disposed between an input line for the jth RS-word symbol Rⱼ and the third register,
wherein the first pipeline multiplexor is configured to receive the first product from the first iterative multiplier, the second pipeline multiplexor is configured to receive the second product from the second iterative multiplier, and
where each of the first and second pipeline multiplexor is respectively configured to select the first product and the second product for a new calculation of Rⱼ×α\hat{ }(i×j) and Rⱼ×α\hat{ }((i+p)×j) while a previous calculation of Rⱼ×α\hat{ }(i×j) and Rⱼ×α\hat{ }((i+p)×j) is still in progress.

8. The hardware circuit of claim 6, further comprising:
a second GF-square hardware unit connected to an output of each first GF-square hardware unit, wherein the GF-square hardware unit is configured to square the α\hat{ }(2j) received from the connected first GF-square hardware unit;
a third iterative multiplier configured to calculate a third product of a result α\hat{ }(4j) received from the second GF-square hardware unit and the result Rⱼ×α\hat{ }(i×j) stored in the second register, and output the third product, and
a fourth iterative multiplier configured to calculate a fourth product of the result α\hat{ }(4j) received from the second GF-square hardware unit and the jth RS-word symbol Rⱼ stored in the third register, and output the second product.

9. The hardware circuit of claim 8, further comprising:
a fourth register disposed between the second GF-square hardware unit and the third iterative multiplier, wherein the fourth register is configured to store the result α\hat{ }(4j) received from the second GF-square hardware unit.
